(19) United States
(12) Patent Application Publication
(10) Pub. No.: US 2010/0096735 A1
(43) Pub. Date: Apr. 22, 2010

(54) CLAMPING ASSEMBLY

(75) Inventors: Xue F. Shen, Singapore (SG); Jing Zhang, Singapore (SG); Nee S. Ling, Singapore (SG); Soo L. Ang, Singapore (SG)

Correspondence Address: SCHWEGMAN, LUNDBERG & WOESSNER, P.A., P.O. BOX 2938, MINNEAPOLIS, MN, 55402, US

(73) Assignee: ROKKO TECHNOLOGY PTE LTD., Singapore (SG)

(21) Appl. No.: 12/523,999

(22) PCT Filed: Nov. 16, 2007
(86) PCT No.: PCT/SG2007/000397

§ 371 Date: Dec. 18, 2009

(30) Foreign Application Priority Data
Dec. 21, 2006 (SG) 200608990-8

(51) Int. Cl. H01L 23/495; H01L 23/48

(52) U.S. Cl. 257/676; 257/669; 257/E23.031; 257/E23.01

(57) ABSTRACT

A clamping assembly for clamping a lead frame with pre-attached semiconductor device, comprising of: a first member, to hold the lead frame, said first member having a surface profile in contact with a surface profile of the semiconductor device, a second member for allowing the mounting of the first member thereon, an attachment means to secure the first member onto the second member, wherein the attachment means is adjustable to conform the surface profile of the first member to the surface profile of the lead frame.

### FIELD OF THE INVENTION

The present invention generally relates to a clamping assembly for clamping lead frames with pre-attached semiconductor devices, such as microchips. In particular, it relates to a clamping assembly having improved provisions for compensating warpages occurring in the lead frame that causes ‘bouncing lead’ (unstable process) when clamping the lead frame, so that wire bonding may be performed.

### BACKGROUND ART

Clamping assemblies known in the art include a top clamp plate to clamp a lead frame with a pre-attached microchip so that wire bonding may be performed on the microchip.

An example of a clamping assembly known in the art is illustrated in FIG. 1. As shown in FIG. 1, the clamping assembly 10 comprises of a top clamp plate 11 as a single entity. The top clamp plate 11 comprises of a relief pocket 13 at both ends. At the central portion of the top clamp plate 11 comprises of at least one rib 12.

Many of the clamping assemblies heretofore devised, including the clamping assembly 10 shown in FIG. 1, however, are not able to sufficiently secure the lead frame when warpages occurs in the lead frame due to pre-heating prior to the wire bonding process of the microchips. As a result of the warpages occurring at the lead frame, the lead frame is insufficiently secured to the clamping assembly. This eventually leads to mechanical or electrical failure of the wire during the wire bonding process of the microchip. As a practical matter, resistance to the extruding action in the wire during “pull-out” tests must meet certain standards to gain approval of the semiconductor device. Semiconductor devices which fail to pass such tests are usually unsaleable.

Therefore, it is important to make some provision in the clamping assembly to allow compensation for warpages in the lead frame. One particular existing method is to paste a yellow adhesive tape underneath the lead frame so as to secure the lead frame to the clamping assemblies. While such method has proven advantageous in use and has gained wide market acceptance, there exists possibilities that these tapes can be removed unintentionally and are therefore not very reliable. Further, the yellow adhesive tape is costly. There may also exist cross contamination when removing the yellow adhesive tape after the wire bonding process. In addition, removing the yellow adhesive tape has proven to be a time consuming procedure.

In view of the foregoing, it is desired to produce a new clamping assembly with improved provisions for compensating warpages in the lead frame with a pre-attached microchip and thereby avoiding or at least partially alleviating at least some of the above problems.

Other objects and advantages of the present invention will become apparent from the following description, taken in connection with the accompanying drawings, wherein, by way of illustration and example, an embodiment of the present invention is disclosed.

### SUMMARY OF THE INVENTION

In accordance with a first aspect of the present invention, there is provided a clamping assembly for clamping lead frame with a pre-attached semiconductor device, comprising of:
a first member, to hold the lead frame, said first member having a surface profile in contact with a surface profile of the lead frame,
a second member for allowing the mounting of the first member thereon,
an attachment means to secure the first member onto the second member,
wherein the attachment means is adjustable to conform the surface profile of the first member to the surface profile of the lead frame.

Preferably, the first member comprises of at least a rib to receive a semiconductor device of the lead frame.

Preferably, the attachment means may be screws.

Preferably, the first member may be made of a flexible material.

In accordance with a second aspect of the present invention, there is provided a clamping devices for clamping a lead frame with a pre-attached semiconductor device, comprising of:
a first member having a plurality of ribs,
a second member for allowing the mounting of the first member thereon,
an attachment means to secure onto the second member,
the ribs having an intersection point hereinbetween,
wherein the intersection point has at least an aperture to compensate for any warpages of the lead frame that caused ‘bouncing lead’ during wire bonding process.

Preferably, the attachment means may be screws.

Preferably, the first member may be made of a flexible material.

In accordance with a third aspect of the present invention, there is provided a clamping devices for clamping a lead frame with a pre-attached semiconductor device, comprising of:
a first member, to hold the lead frame,
a second member for allowing the mounting of the first member thereon,
an attachment means to secure the first member onto the second member, the second member having relief pockets at both ends,
wherein the relief pockets compensate any warpages of the lead frame.

Preferably, the first member comprises of a plurality of ribs.

Preferably, the attachment means may be screws.

Preferably, the first member may be made of a flexible material.

### BRIEF DESCRIPTION OF THE FIGURES

Further objects of this invention, together with additional features contributing thereto and advantages accruing therefrom, will be apparent from the following description of an embodiment of the present invention which is shown in the accompanying drawings with like reference numerals indicating corresponding parts throughout and which is to be read in conjunction with the following drawings, wherein:

FIG. 1 shows an example of a clamping assembly known in the art.

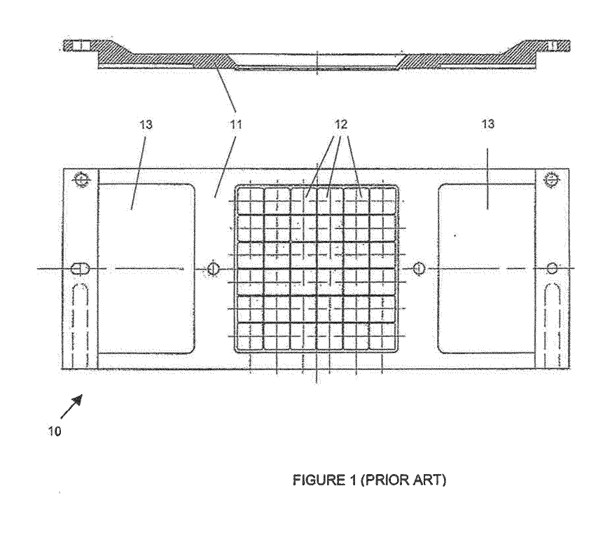

FIG. 2 shows a perspective view of an exemplary clamping assembly 1 in accordance with one embodiment of the present invention.

FIG. 3 shows an exploded view of clamping assembly 1 in accordance with one embodiment of the present invention.

FIG. 4 shows the clamping of the lead frame onto the clamping assembly.

FIG. 5 shows the clamping assembly and the lead frame after the completion of the wire bonding process.

These and additional embodiments of the invention may now be better understood by turning to the following detailed description wherein an illustrated embodiment is described.

### DETAILED DESCRIPTION OF THE PREFERRED EMBODIMENTS

Throughout this description, the embodiments and examples shown should be considered as exemplars, rather than limitations on the apparatus of the present invention.

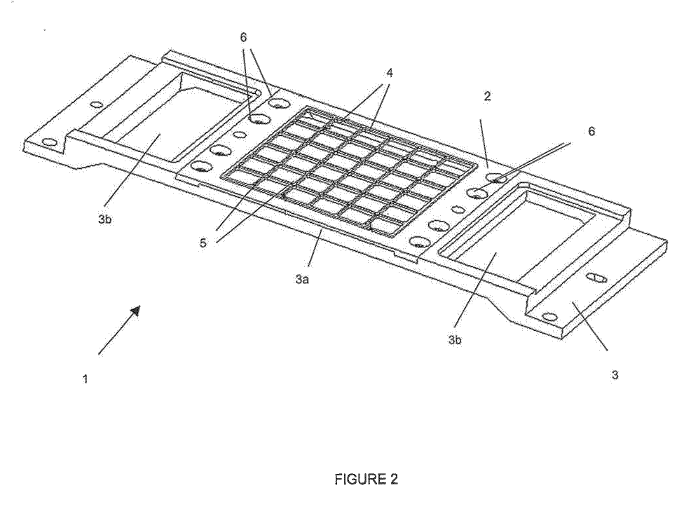

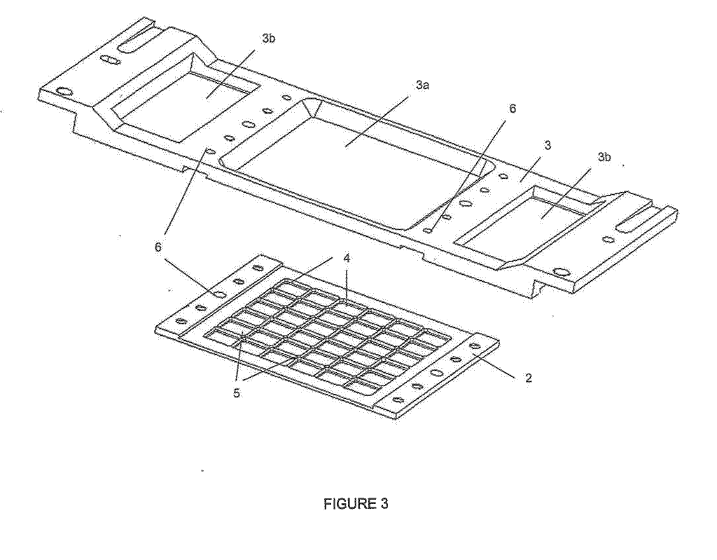

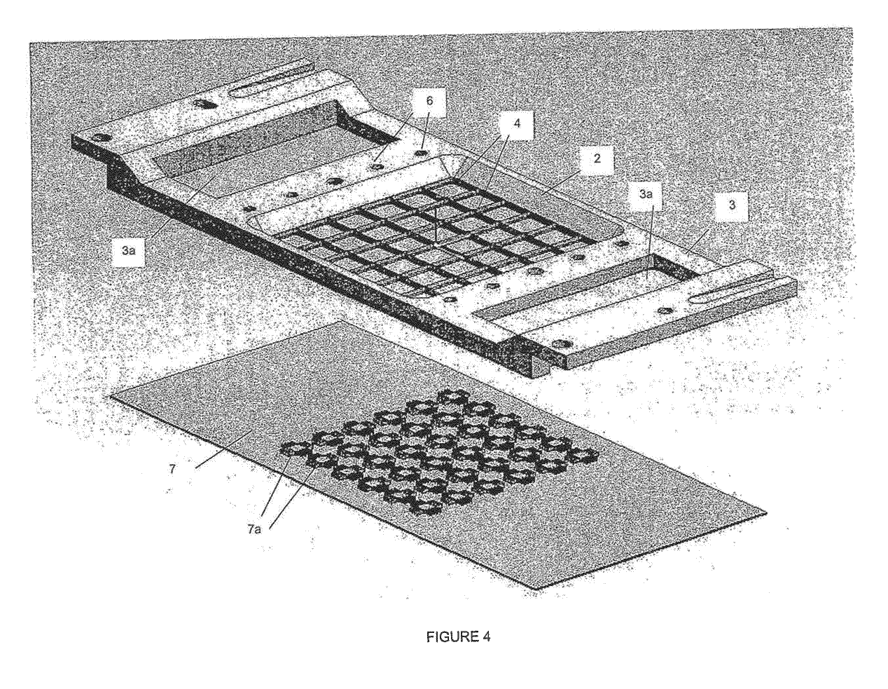

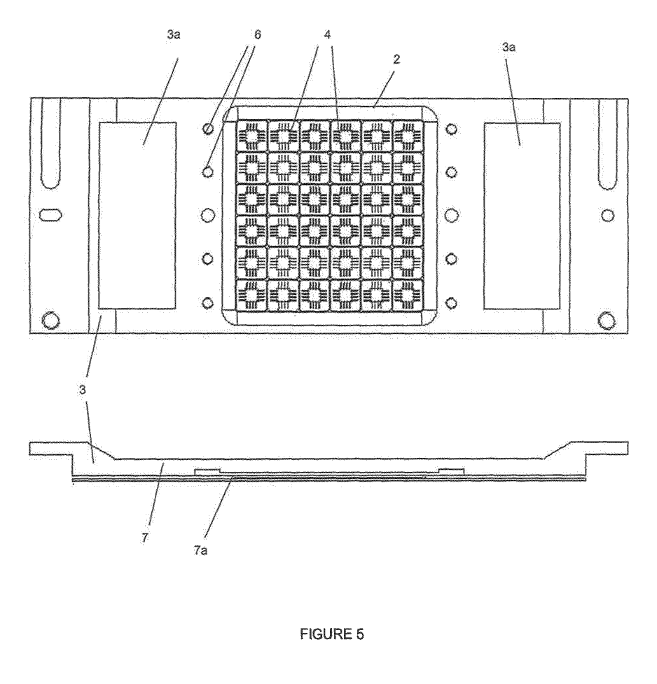

FIG. 2 shows a perspective view of an exemplary clamping assembly 1 in accordance with one embodiment of the present invention. FIG. 3 shows an exploded view of the clamping assembly 1 in accordance with one embodiment of the present invention. FIG. 4 shows the clamping of the lead frame onto the clamping assembly. FIG. 5 shows the clamping assembly and the lead frame after the completion of the wire bonding process.

The present invention relates to a clamping assembly for clamping a lead frame with a pre-attached semiconductor device.

The clamping assembly 1 is elongate and generally rectangular in shape when viewed from above. As seen in FIG. 2, the clamping assembly includes a first member 2 and a second member 3. The first member 2, known as an insert member, and a second member 3 dimensioned to receive the first member 2. As shown, the insert member 2 comprises of at least one rib 4.

The second member 3, which may be known as a holding plate member, includes a mounting portion 3a, to accommodate the insert member 2 thereupon. The mounting portion 3a has at least the same dimension as the insert member, so as to permit mounting of the insert member 2 thereon.

As shown in FIG. 4, when in use, the lead frame 7 is mounted in between the insert member 2 and a heating plate (not shown). The lead frame 7 may have a plurality of semiconductor devices, such as microchips 7a being attached thereto and arranged in an predetermined pattern of array as shown, each microchip 7a arranged corresponding to individual ribs 4 of the insert member 2. After the lead frame 7 is secured onto the clamping assembly 1, wire bonding is performed on the microchip 7a so as to connect the microchip 7a electrically to the leads of the lead frame 7, as shown in FIG. 5.

As discussed earlier, warpages normally occur at the lead frame 7 due to heating prior to the wire bonding process of the microchip. This causes the surface profile of the microchip to be irregular. The warpages on the lead frame may occur in the direction longitudinal to the insert member. Due to the warpages on the lead frame 7, stress is imparted onto the insert member 2. Such warpages are not desired as they would cause the lead frame to be insufficiently secured to the clamping assembly. This eventually leads to mechanical or electrical failure of the wire during the wire bonding process of the microchip. As a practical matter, resistance to the extruding action in the wire during “pull-out” tests must meet certain standards to gain approval of the semiconductor device. Microchips which fail to pass such tests are usually unsaleable.

It is submitted that the compensation of the warpages of the lead frame can be achieved by certain provisions of the present invention as described hereinafter.

As shown in FIGS. 2 and 3, a hole 5 is drilled at the intersection point of the ribs 4 for the purpose of compensating the warpages of the lead frame 7. It will be appreciated that there may be more than one hole drilled at the intersection point of the ribs 4. The size of the ribs 4 on the insert member 2 may also be reduced to minimize errors during wire bonding.

When the insert member 2 is mounted onto the holding plate member 3, attachment means are introduced to maintain the relative position between the holding plate member 3 and insert member 2. The attachment means (not shown), such as screws, may be extended into the screw holes 6 to thereby secure the two members together. The screws prevent rotation of the members during operation. The screws may be further sealed to prevent unauthorized or accidental adjustment. Further, the screws may also be adjusted so that the surface profile of the insert member 2 is able to match the warpage profile of the lead frame 7 so that it may be sufficiently secured. Studies have shown that the warpage profile of the lead frame 7 normally occurs longitudinally to the insert member 2.

The insert member 2 may preferably be made of a flexible material so that the surface profile may be easily manipulated to match the warpage profile of the lead frame 7. An example of such a material is a spring steel.

The holding plate member 3 may also have a relief pocket 3b near each end of the holding plate member 3, as shown in the figures. Studies have shown that the relief pocket 3b may act as a stress relief, due to the increased area in which the forces could act. Thus, the relief pockets 3b can assist in the compensation of the warpages of the lead frame 7.

It will be understood that most of the structure of the above example can be changed without departing from the scope of the invention. For example, the number, position and shape of the ribs can vary according to the configuration of the semiconductor device, or according to various other requirements or preferences. The pocket size can be any desired shape, straight or curved of any number of portions, extending from any side, as appropriate. Likewise the size and shape of the screw holes 6 can vary according to the circumstances.

The design of the insert member 2 and holding plate member 3 can also be changed as required. The above described embodiment is intended for mounting of the holding plate member 3 onto the insert member 2. Other mounting possibilities exist. Additionally, other embodiments, at least within some aspects of the invention can be intended. In such an instance, for example, the insert member may be designed in such a way that it is possible to have more than one holding plate member 3 being mounted thereon. Other mounting possibilities are also available as required by the configuration of the relevant clamp assembly or wire bonding machine.

The clamping assembly of the invention is easy to fit and use. It provides means of securing the semiconductor device thereon by improved provision of compensating the warpages in the lead frame, and thereby resulting in lesser rejected semiconductor devices. It also improves the durability of the clamping assembly. The insert member and holding plate member are fabricated such that they move independently of each other to self-adjust and accommodate the varying thicknesses of the semiconductor devices or other variations. The insert member or holding plate member can be replaced with another of a different configuration with relative ease and speed, as long as they serve the same purpose.

Many other variations are possible within the scope of the present invention which is only limited as defined in the claims or elsewhere as indicated.

1. A clamping assembly for clamping a lead frame with a pre-attached semiconductor device, comprising of:
a first member, to hold the lead frame, said first member having a surface profile in contact with a surface profile of the lead frame,
a second member for allowing the mounting of the first member thereon,
an attachment means to secure the first member onto the second member,
wherein the attachment means is adjustable to conform the surface profile of the first member to the surface profile of the lead frame.

2. The clamping assembly according to claim 1, wherein the first member comprises of at least a rib to receive a semiconductor device of the lead frame.

3. The clamping assembly according to any one of the preceding claims claim 1, wherein the attachment means may be screws.

4. The clamping assembly according to any one of the preceding claims claim 1, wherein the first member may be made of a flexible material.

5. A clamping devices assembly for clamping a lead frame with a pre-attached semiconductor device, comprising of:
a first member having a plurality of ribs,
a second member for allowing the mounting of the first member thereon,
an attachment means to secure onto the second member,
the ribs having an intersection point hereinbetween,
wherein the intersection point has at least an aperture to compensate for any warpages of the lead frame that causes ‘bouncing lead’ (unstable process).

6. The clamping assembly according to claim 5, wherein the attachment means may be screws.

7. The clamping assembly according to claim 5, wherein the first member may be made of a flexible material.

8. A clamping assembly for clamping a lead frame with a pre-attached semiconductor device, comprising of:
a first member, to hold the lead frame,
a second member for allowing the mounting of the first member thereon,
an attachment means to secure the first member onto the second member,
the second member having relief pockets at both ends,
wherein the relief pockets compensate any warpages of the lead frame.

9. The clamping assembly according to claim 8, wherein the first member comprises of a plurality of ribs.

10. The clamping assembly according to claim 8, wherein the attachment means may be screws.

11. The clamping assembly according to claim 8, wherein the first member may be made of a flexible material.
